(19) United States
(12) Patent Application Publication
(10) Pub. No.: US 2008/0280440 A1
(43) Pub. Date: Nov. 13, 2008

(54) METHOD FOR FORMING A PN DIODE AND METHOD OF MANUFACTURING PHASE CHANGE MEMORY DEVICE USING THE SAME

(76) Inventor: Heon Yong CHANG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 11/938,486

(22) Filed: Nov. 12, 2007

(30) Foreign Application Priority Data
May 11, 2007 (KR) 10-2007-0046133

(51) Int. Cl. H01L 21/441

(52) U.S. Cl. 438/684; 257/E21.477

(57) ABSTRACT

Disclosed is a method of forming a PN diode and a method of manufacturing a phase change memory device using the same. Formation of a PN diode includes forming a first conductivity type region in a surface of a semiconductor substrate. A polysilicon layer doped with second conductivity type impurities is then deposited on the semiconductor substrate formed with the first conductivity type region. Forming a plurality of second conductivity type regions by etching the polysilicon layer doped with the second conductivity type impurities completes the PN diode. Since the P-regions of a PN diode are formed through the deposition and etching of a polysilicon layer doped with second conductivity type impurities rather than an SEG process, a uniformity of resistance in the PN diode can be obtained.

### CROSS-REFERENCE TO RELATED APPLICATIONS

The present application claims priority to Korean patent application number 10-2007-0046133 filed on May 11, 2007, which is incorporated herein by reference in its entirety.

### BACKGROUND OF THE INVENTION

The present invention relates to a method of manufacturing a phase change memory device, and more particularly, to a method of forming a PN diode capable of forming stable P-regions and a method of manufacturing a phase change memory device using the same.

In general, memory devices are largely divided between volatile RAM (random access memory), which loses inputted information when power is interrupted, and non-volatile ROM (read-only memory), which can continuously maintain the stored state of inputted information even when power is interrupted. Examples of volatile RAM include DRAM (dynamic RAM) and SRAM (static RAM). An example of non-volatile ROM includes flash memory such as an EEPROM (electrically erasable and programmable ROM).

As is well known in the art, DRAM is an excellent memory device. However, DRAM must have a high charge storing capacity requiring the surface area of an electrode to be increased making it difficult to accomplish a high level of integration. Further, in flash memory, two gates are stacked on each other requiring a high operation voltage as compared to a source voltage. It is therefore difficult to accomplish a high level of integration since a separate booster circuit is needed to form a voltage necessary for write and delete operations.

To address these problems research has been made in an effort to develop a novel memory device having a simple configuration and capable of accomplishing a high level of integration while retaining the characteristics of a non-volatile memory device. For example, a phase change memory device has recently been disclosed in the art.

In a phase change memory device, a phase change occurs in a phase change layer interposed between a lower electrode and an upper electrode from a crystalline state to an amorphous state. The phase change is due to current flow between the lower electrode and the upper electrode. The information stored in a cell is recognized by the medium of a difference in resistance between the crystalline state and the amorphous state.

In a phase change memory device, a CMOS transistor or a PN diode can be used as a switching element. A phase change memory device using a PN diode is disclosed in a paper entitled “A 1.8V 113 MHz 512 Mb PRAM Using Vertical Diode Switches.”

The phase change memory device using the PN diode as a switching element is advantageous in that it has a high degree of current flow when compared to the phase change memory device using the CMOS transistor and also possible to decrease the size of a cell.

FIG. 1 is a cross-sectional view illustrating a conventional phase change memory device using a PN diode.

Referring to FIG. 1, an N-region 102 is formed on the surface of a semiconductor substrate 100. P-regions 104 are formed on the N-region 102 whereby a PN diode 110 is configured. The P-regions 104 are formed using a selective epitaxial growth (SEG) process.

A lower electrode 120 is formed in the shape of a plug to contact each P-region 104 of the PN diode 110. A phase change layer 132 and an upper electrode 134 are stacked on the lower electrode 120. A bit line 170 is formed to contact the upper electrode 134 and a word line 180 is formed over the bit line 170 to contact the N-region 102.

In the phase change memory device using the PN diode 110, a current flow path is defined to extend from the bit line 170 through the upper electrode 134, the phase change layer 132 and the lower electrode 120 and via the P-region 104 and the N-region 102 of the PN diode 110 to the word line 180. Depending upon whether the phase change layer 132 is in an amorphous state or a crystalline state, the amount of current flowing to the word line 180 changes, whereby a difference in voltage is caused between bit lines 170.

However, in the conventional phase change memory device using the PN diode, since the P-region 104 of the PN diode 110 is formed using the SEG process, a non-uniformity of resistance results. Further, due to this non-uniformity of resistance, the range of the programming current when using the PN diode is enlarged and as a result, difficulties exist in securing stable characteristics for the phase change memory device.

### SUMMARY OF THE INVENTION

Embodiments of the present invention are directed to a method of forming a PN diode which can stably form P-regions.

Also, embodiments of the present invention are directed to a method of forming a phase change memory device which can stably form P-regions and thereby stably secure the characteristics of the phase change memory device.

In one aspect, a method of forming a PN diode comprises the steps of forming a first conductivity type region in a surface of a semiconductor substrate; depositing a polysilicon layer doped with second conductivity type impurities on the semiconductor substrate formed with the first conductivity type region; and forming a plurality of second conductivity type regions by etching the polysilicon layer doped with the second conductivity type impurities.

The first conductivity type region is an N-region, and the second conductivity type regions are P-regions.

The semiconductor substrate formed with the first conductivity type region includes a bar type active region.

The first conductivity type region is formed on a surface of the active region into a bar type.

The second conductivity type regions are formed such that predetermined numbers of the second conductivity type regions spaced apart at first regular intervals are spaced apart at second regular intervals which are greater than the first intervals.

In another aspect, a method of manufacturing a phase change memory device comprises the steps of depositing a polysilicon layer doped with second conductivity type impurities on a semiconductor substrate which is formed with a first conductivity type region in a surface thereof; etching the polysilicon layer doped with the second conductivity type impurities and thereby forming second conductivity type regions which constitute a PN diode in cooperation with the first conductivity type region; forming a first insulation layer on the semiconductor substrate to cover the PN diode; chemical-mechanical polishing (“CMPing”) the first insulation layer to expose the second conductivity type regions; forming a second insulation layer on the first insulation layer; forming lower electrodes in the second insulation layer to come into contact with the second conductivity type regions; and stacking a phase change layer and upper electrodes on the lower electrodes.

After the step of stacking the phase change layer and the upper electrodes, the method further comprises the steps of forming a third insulation layer on the second insulation layer including the phase change layer and the upper electrodes; forming first contact plugs in the third insulation layer, the second insulation layer and the first insulation layer to come into contact with the first conductivity type region; forming a fourth insulation layer on the third insulation layer including the first contact plugs; forming upper electrode contacts in the fourth insulation layer and the third insulation layer to come into contact with the upper electrodes; forming bit lines on the fourth insulation layer to come into contact with the upper electrode contacts; forming a fifth insulation layer on the fourth insulation layer including the bit lines; forming second contact plugs in the fifth insulation layer and the fourth insulation layer to come into contact with the first contact plugs; and forming a word line on the fifth insulation layer to come into contact with the second contact plugs and with the first conductivity type region through the second contact plugs and the first contact plugs.

In still another aspect, a method of forming a PN diode comprises the steps of forming a first conductivity type region in a surface of a semiconductor substrate; depositing an insulation layer on the semiconductor substrate formed with the first conductivity type region; etching the insulation layer and thereby defining a plurality of holes to expose the first conductivity type region; depositing a polysilicon layer doped with second conductivity type impurities on the insulation layer to fill the plurality of holes; and CMPing the polysilicon layer doped with the second conductivity type impurities until the insulation layer is exposed and thereby forming second conductivity type regions in the respective holes.

The first conductivity type region is an N-region, and the second conductivity type regions are P-regions.

The semiconductor substrate formed with the first conductivity type region includes a bar type active region.

The first conductivity type region is formed on a surface of the active region into a bar type.

The holes are defined such that predetermined numbers of the holes spaced apart at first regular intervals are spaced apart at second regular intervals which are greater than the first intervals.

In a still further aspect, a method of manufacturing a phase change memory device comprises the steps of forming a first insulation layer on a semiconductor substrate which is formed with a first conductivity type region in a surface thereof; etching the first insulation layer and thereby defining a plurality of holes to expose the first conductivity type region; filling a polysilicon layer doped with second conductivity type impurities in the respective holes and thereby forming second conductivity type regions which constitute a PN diode in cooperation with the first conductivity type region; forming a second insulation layer on the first insulation layer including the second conductivity type regions; forming lower electrodes in the second insulation layer to come into contact with the second conductivity type regions; and stacking a phase change layer and upper electrodes on the lower electrodes.

After the step of stacking the phase change layer and the upper electrodes, the method further comprises the steps of forming a third insulation layer on the second insulation layer including the phase change layer and the upper electrodes; forming first contact plugs in the third insulation layer, the second insulation layer and the first insulation layer to come into contact with the first conductivity type region; forming a fourth insulation layer on the third insulation layer including the first contact plugs; forming upper electrode contacts in the fourth insulation layer and the third insulation layer to come into contact with the upper electrodes; forming bit lines on the fourth insulation layer to come into contact with the upper electrode contacts; forming a fifth insulation layer on the fourth insulation layer including the bit lines; forming second contact plugs in the fifth insulation layer and the fourth insulation layer to come into contact with the first contact plugs; and forming a word line on the fifth insulation layer to come into contact with the second contact plugs and with the first conductivity type region through the second contact plugs and the first contact plugs.

### BRIEF DESCRIPTION OF THE DRAWINGS

FIG. 1 is a cross-sectional view illustrating a conventional phase change memory device using a PN diode.

FIGS. 2A and 2B are cross-sectional views illustrating the processes for a method of forming a PN diode in accordance with an embodiment of the present invention.

FIGS. 3A through 3E are cross-sectional views illustrating the processes for a method of manufacturing a phase change memory device in accordance with another embodiment of the present invention.

FIGS. 4A through 4C are cross-sectional views illustrating the processes for a method of forming a PN diode in accordance with still another embodiment of the present invention.

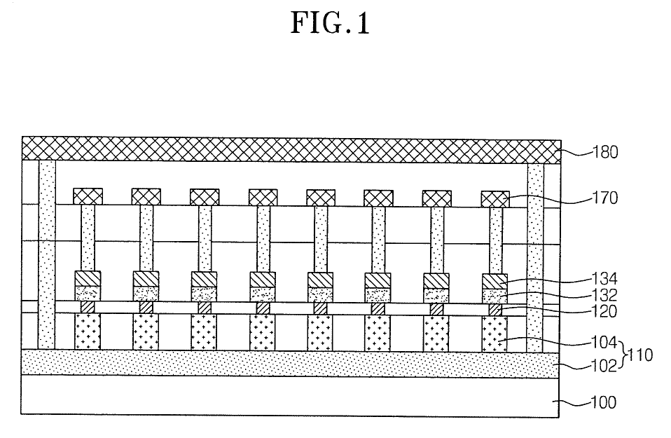

### DESCRIPTION OF SPECIFIC EMBODIMENTS

In the present invention, P-regions are formed by sequentially conducting processes for depositing a polysilicon layer doped with P-type impurities on a semiconductor substrate and etching the polysilicon layer forming a PN diode.

Therefore, in the present invention, by forming the P-regions through deposition and etching of the P-type polysilicon layer, the non-uniformity of resistance in the P-regions can be decreased as compared to the use of the SEG process in the conventional art. Accordingly, in the present invention, the characteristics of the PN diode are improved since the P-regions are stably formed. Therefore, it is possible to realize a phase change memory device having stable characteristics.

Hereafter, specific embodiments of the present invention will be described with reference to the attached drawings.

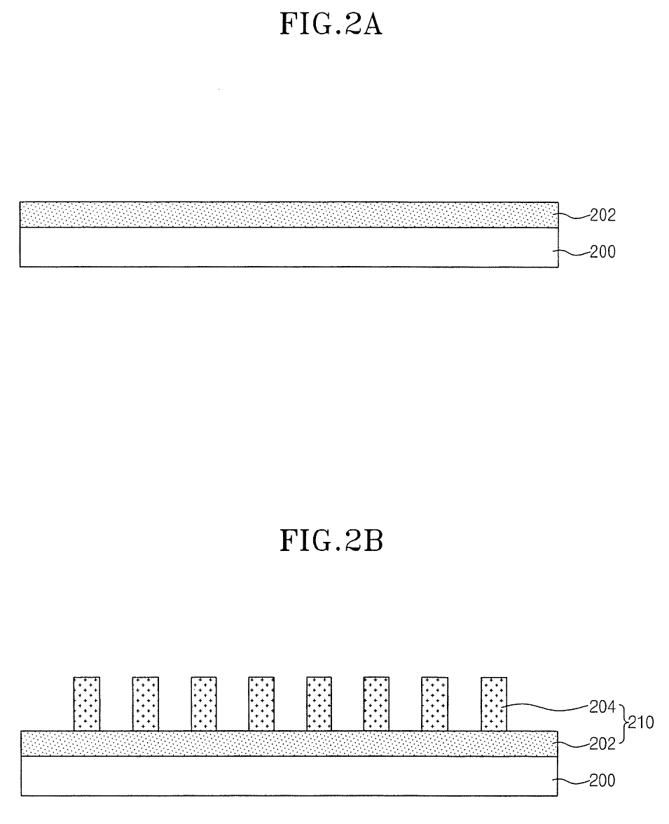

FIGS. 2A and 2B are cross-sectional views illustrating the processes for a method of forming a PN diode in accordance with an embodiment of the present invention.

Referring to FIG. 2A, a first conductivity type region, i.e., N-region 202, is formed in the surface of a semiconductor substrate 200 through an ion implantation process. Here, the semiconductor substrate 200 formed with the N-region 202 includes a bar type active region. It can therefore be understood that the N-region 202 is formed in the surface of the active region in a bar shape.

Referring to FIG. 2B, a polysilicon layer doped with second conductivity type impurities, i.e., P-type impurities, is deposited on the semiconductor substrate 200 formed with the N-region 202. By etching the polysilicon layer doped with the P-type impurities, a plurality of P-regions 204 are formed on the N-region 202 forming a PN diode 210. The P-regions 204 are formed in a pole shape such that a predetermined number of the P-regions 204 spaced apart at first regular intervals are spaced apart at second regular intervals which are greater than the first intervals.

As is apparent from the above description, in the PN diode according to the present invention, P-regions 204 are not formed via an SEG process, but rather through the deposition and etching processes. Accordingly, the P-regions can have a uniform resistance and the PN diode according to the present invention can have improved characteristics.

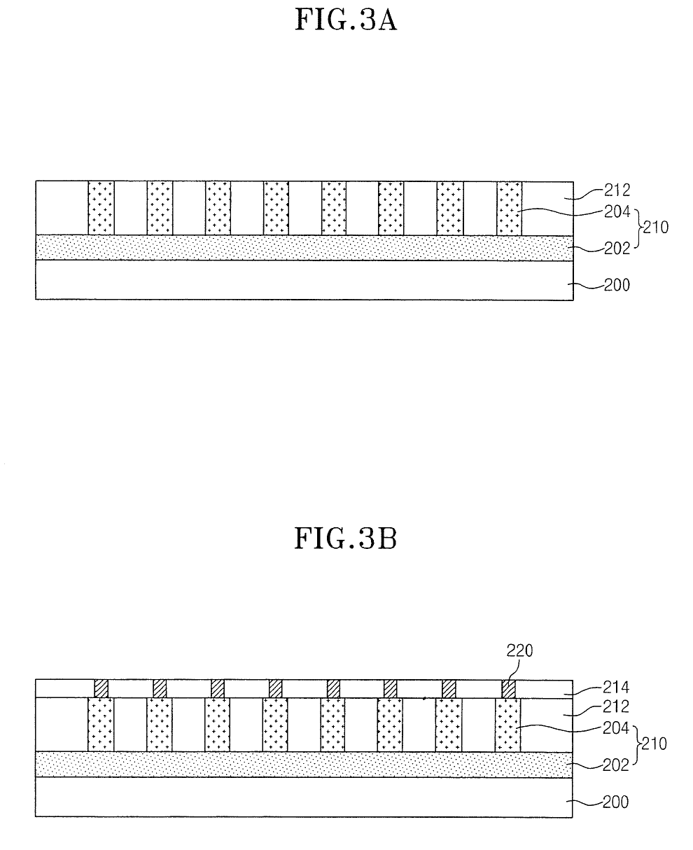

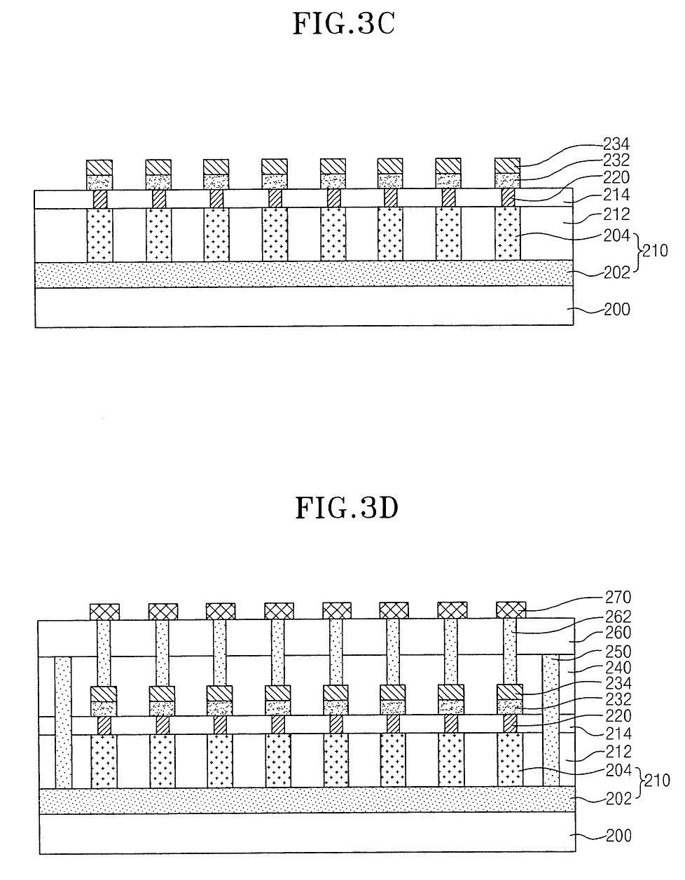

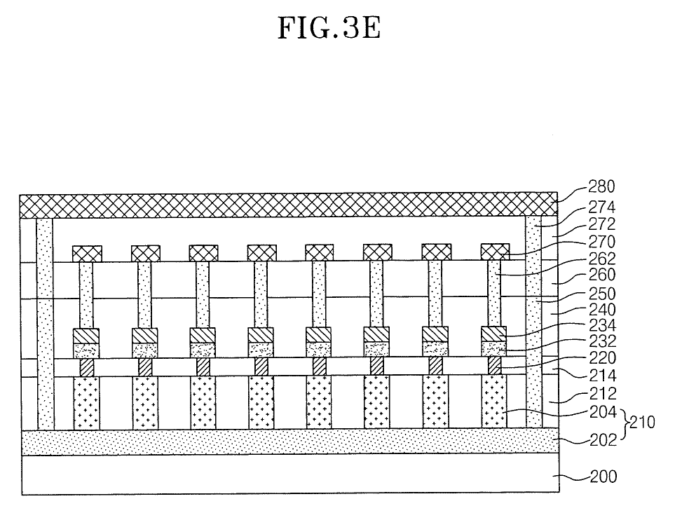

FIGS. 3A through 3E are cross-sectional views illustrating the processes for a method of manufacturing a phase change memory device in accordance with another embodiment of the present invention.

Referring to FIG. 3A, a first insulation layer 212 is deposited on the semiconductor substrate 200 that is formed with the PN diode 210 composed of the N-region 202 and the P-regions 204. Then, the first insulation layer 212 is chemically and mechanically polished (“CMPed”) until the P-regions 204 are exposed.

Referring to FIG. 3B, a nitride-based second insulation layer 214 is deposited on the first insulation layer 212 including the exposed P-regions 204. First contact holes are defined to respectively expose the P-regions 204 of the PN diode 210 by etching the second insulation layer 214. A conductive layer for lower electrodes is deposited on the second insulation layer 214 to fill the first contact holes. Lower electrodes 220 are formed in the respective first contact holes to contact the P-regions 204 by chemical-mechanical polishing (“CMPing”) the conductive layer for lower electrodes until the second insulation layer 214 is exposed. The nitride-based second insulation layer 214 is formed to prevent the heat transferred from the lower electrodes 220 to a subsequently formed phase change layer from being dissipated. The conductive layer for lower electrodes is formed of a material having low reactivity with the phase change layer, i.e., having low heat conductivity and high resistance. The conductive layer for lower electrodes may be formed using any one of TiW, TiN and TiAlN.

Referring to FIG. 3C, a phase change material layer and a conductor layer for upper electrodes are sequentially deposited on the second insulation layer 214 including the lower electrodes 220. The phase change material layer is formed using a compound containing at least one of Ge, Sb and Te. Any one of oxygen, nitrogen and silicon is doped into the surface of the phase change material layer. The conductive layer for upper electrodes is formed of a material having low heat conductivity. Accordingly, since the heat transferred to the phase change layer can be prevented from dissipating to the upper electrodes, etc., the efficiency of Joule's heat can be improved. A stack pattern of a phase change layer 232 and upper electrodes 234 is formed on the lower electrodes 220 by etching the conductive layer for upper electrodes and the phase change material layer.

Referring to FIG. 3D, a third insulation layer 240 is formed on the second insulation layer 214 including the stack pattern of the phase change layer 232 and the upper electrodes 234. Second contact holes are defined by etching the third insulation layer 240, the second insulation layer 214, and the first insulation layer 212 to expose the N-region 202. First contact plugs 250 are formed by filling a conductive layer in the second contact holes. Each first contact plug 250 is formed to contact the portion of the N-region 202 that is positioned between the predetermined numbers of P-regions 204 spaced apart at the second regular interval. The voltage applied from a subsequently formed word line can then reach the N-region 202.

A fourth insulation layer 260 is formed on the third insulation layer 240 including the first contact plugs 250. Third contact holes are defined for respectively exposing the upper electrodes 234 by etching the fourth insulation layer 260 and the third insulation layer 240. Filling a conductive layer in the third contact holes forms upper electrode contacts 262. A conductive layer is deposited on the fourth insulation layer 260 including the upper electrode contacts 262. Bit lines 270 are formed to contact the respective upper electrode contacts 262 by etching the conductive layer. The bit lines 270 are formed parallel to the bar-type N-region 202.

Referring to FIG. 3E, a fifth insulation layer 272 is formed on the fourth insulation layer 260 including the bit lines 270. Fourth contact holes are defined for exposing the first contact plugs 250 by etching the fifth insulation layer 272 and the fourth insulation layer 260. By filling a conductive layer in the fourth contact holes, second contact plugs 274 are formed to contact the respective first contact plugs 250. A conductive layer is deposited on the fifth insulation layer 272 including the second contact plugs 274. Etching the conductive layer forms a word line 280 to contact the second contact plugs 274.

The manufacture of the phase change memory device using a PN diode in accordance with the present embodiment of the present invention is completed by sequentially conducting a series of subsequent well-known processes (not shown).

As is apparent from the above description, in the phase change memory device according to the present embodiment, the P-regions of a PN diode are formed by depositing and etching a polysilicon layer doped with P-type impurities. As a result, the characteristics of the phase change memory device can be stably secured through the stable formation of the P-regions.

As described in the aforementioned embodiment, the P-regions of a PN diode are formed through sequentially conducting deposition and etching processes of a polysilicon layer doped with P-type impurities. In another embodiment of the present invention, the P-regions can be formed through a damascene process.

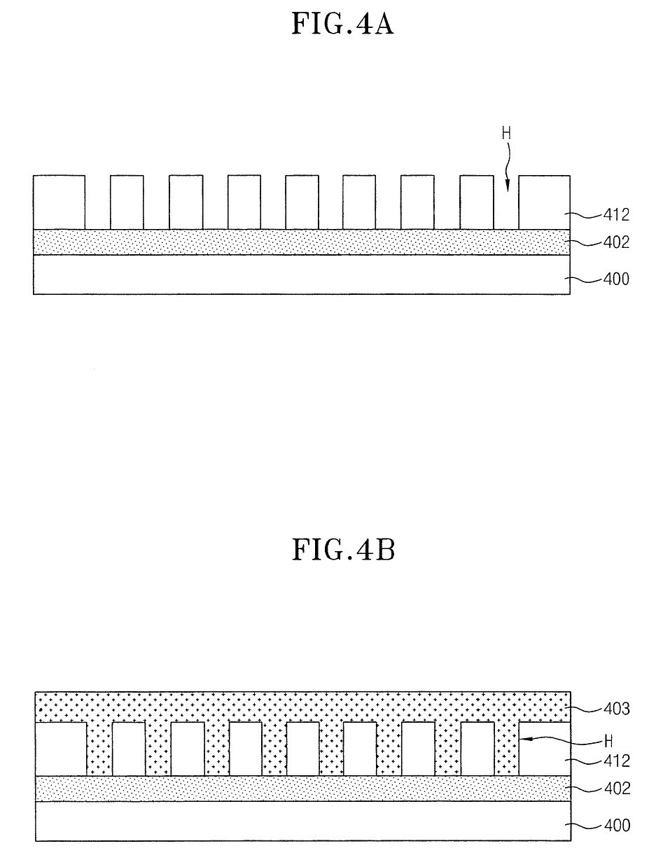

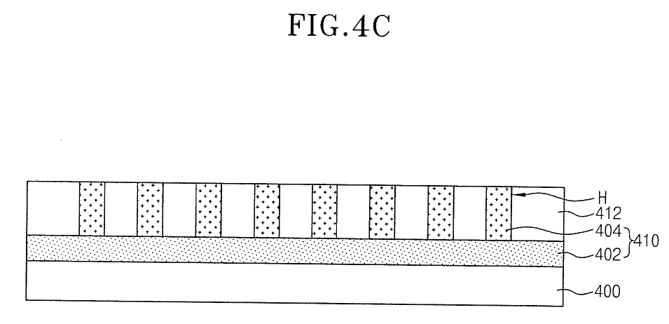

FIGS. 4A through 4C are cross-sectional views illustrating the processes for a method of a forming a PN diode in accordance with still another embodiment of the present invention.

Referring to FIG. 4A, a first insulation layer 412 is formed on a semiconductor substrate 400 that is formed with a first conductivity type region, i.e., an N-region 402. A plurality of holes H for exposing the N-region 402 are defined by etching the first insulation layer 412. The holes H are defined such that predetermined numbers of the holes H spaced apart at first regular intervals are spaced apart at second regular intervals.

Referring to FIG. 4B, a polysilicon layer 403 doped with second conductivity type impurities, i.e., P-type impurities, is deposited on the first insulation layer 412 to fill the holes H.

Referring to FIG. 4C, by CMPing the polysilicon layer 403 doped with the P-type impurities, P-regions 404 are formed in the respective holes H to contact the N-region 402, thereby forming a PN diode 410.

In the method of forming a PN diode according to the present embodiment, similar to the aforementioned embodiment, since the P-regions of a PN diode are formed through the deposition and etching of a polysilicon layer doped with P-type impurities rather than an SEG process, the uniformity of resistance in the PN diode can be obtained.

Although not illustrated in the drawings, according to a still further embodiment of the present invention, the semiconductor substrate formed with the PN diode can be used to manufacture a phase change memory device through the same processes as shown in FIGS. 4A through 4C.

As is apparent from the above description, in the phase change memory device using a PN diode according to the present invention, since the P-regions of a PN diode are formed through the deposition and etching of a polysilicon layer rather than an SEG process of the conventional art, the P-regions can be stably formed and it is possible to stably secure the characteristics of the phase change memory device.

Although specific embodiments of the present invention have been described for illustrative purposes, those skilled in the is art will appreciate that various modifications, additions and substitutions are possible, without departing from the scope and the spirit of the invention as disclosed in the accompanying claims.

What is claimed is:

1. A method of forming a PN diode, comprising the steps of:
forming a first conductivity type region in a portion of a semiconductor substrate;
depositing a polysilicon layer doped with second conductivity type impurities on the semiconductor substrate formed with the first conductivity type region; and
forming a plurality of second conductivity type regions by etching the polysilicon layer doped with the second conductivity type impurities.

2. The method according to claim 1, wherein the first conductivity type region is an N-region, and the second conductivity type regions are P-regions.

3. The method according to claim 1, wherein the semiconductor substrate formed with the first conductivity type region includes a bar type active region.

4. The method according to claim 3, wherein the first conductivity type region is formed on a surface of the active region into a bar type.

5. The method according to claim 1, wherein the second conductivity type regions are formed such that predetermined numbers of the second conductivity type regions spaced apart at first regular intervals are spaced apart at second regular intervals which are greater than the first intervals.

6. A method of forming a PN diode, comprising the steps of:
forming a first conductivity type region in a surface of a semiconductor substrate;
depositing an insulation layer on the semiconductor substrate formed with the first conductivity type region;
etching the insulation layer so as to define a plurality of holes to expose the first conductivity type region;
depositing a polysilicon layer doped with second conductivity type impurities on the insulation layer to fill the plurality of holes; and
chemical-mechanical polishing (“CMPing”) the polysilicon layer doped with the second conductivity type impurities until the insulation layer is exposed and thereby forming second conductivity type regions in the respective holes.

7. The method according to claim 6, wherein the first conductivity type region is an N-region, and the second conductivity type regions are P-regions.

8. The method according to claim 6, wherein the semiconductor substrate formed with the first conductivity type region includes a bar type active region.

9. The method according to claim 8, wherein the first conductivity type region is formed on a surface of the active region into a bar type.

10. The method according to claim 6, wherein the holes are defined such that predetermined numbers of the holes spaced apart at first regular intervals are spaced apart at second regular intervals which are greater than the first intervals.

11. A method of manufacturing a phase change memory device, comprising the steps of:
depositing a polysilicon layer doped with second conductivity type impurities on a semiconductor substrate which is formed with a first conductivity type region in a surface thereof;
etching the polysilicon layer doped with the second conductivity type impurities and thereby forming second conductivity type regions which constitute a PN diode including the first conductivity type region;
forming a first insulation layer on the semiconductor substrate to cover the PN diode;
CMPing the first insulation layer to expose the second conductivity type regions;
forming a second insulation layer on the first insulation layer;
forming lower electrodes in the second insulation layer by etching the second insulation layer to contact the second conductivity type regions; and
stacking a phase change layer and upper electrodes on the lower electrodes.

12. The method according to claim 11, wherein, after the step of stacking the phase change layer and the upper electrodes, the method further comprises the steps of:
forming a third insulation layer on the second insulation layer including the phase change layer and the upper electrodes;
forming first contact plugs through the third insulation layer, the second insulation layer, and the first insulation layer to contact the first conductivity type region;
forming a fourth insulation layer on the third insulation layer including the first contact plugs;
forming upper electrode contacts through the fourth insulation layer and the third insulation layer to contact the upper electrodes;
forming bit lines on the fourth insulation layer to contact the upper electrode contacts;
forming a fifth insulation layer on the fourth insulation layer including the bit lines;
forming second contact plugs through the fifth insulation layer and the fourth insulation layer to contact the first contact plugs; and
forming a word line on the fifth insulation layer to contact the second contact plugs thereby connecting the word line to the first conductivity type region through the second contact plugs contacting the first contact plugs.

13. The method according to claim 11, wherein the first conductivity type region is an N-region, and the second conductivity type regions are P-regions.

14. The method according to claim 11, wherein the semiconductor substrate formed with the first conductivity type region includes a bar type active region.

15. The method according to claim 14, wherein the first conductivity type region is formed on a surface of the active region into a bar type.

16. The method according to claim 11, wherein the second conductivity type regions are formed such that predetermined numbers of the second conductivity type regions spaced apart at first regular intervals are spaced apart at second regular intervals which are greater than the first intervals.

17. A method of manufacturing a phase change memory device, comprising the steps of:
forming a first insulation layer on a semiconductor substrate which is formed with a first conductivity type region in a surface thereof;
etching the first insulation layer and thereby defining a plurality of holes to expose the first conductivity type region;
filling a polysilicon layer doped with second conductivity type impurities in the respective holes and thereby forming second conductivity type regions which constitute a PN diode including the first conductivity type region;
forming a second insulation layer on the first insulation layer including the second conductivity type regions;
forming lower electrodes in the second insulation layer to contact the second conductivity type regions; and
stacking a phase change layer and upper electrodes on the lower electrodes.

18. The method according to claim 17, wherein, after the step of stacking the phase change layer and the upper electrodes, the method further comprises the steps of:
forming a third insulation layer on the second insulation layer including the phase change layer and the upper electrodes;
forming first contact plugs in the third insulation layer, the second insulation layer and the first insulation layer to contact the first conductivity type region;
forming a fourth insulation layer on the third insulation layer including the first contact plugs;
forming upper electrode contacts through the fourth insulation layer and the third insulation layer to contact the upper electrodes;
forming bit lines on the fourth insulation layer to contact the upper electrode contacts;
forming a fifth insulation layer on the fourth insulation layer including the bit lines;
forming second contact plugs through the fifth insulation layer and the fourth insulation layer to contact the first contact plugs; and
forming a word line on the fifth insulation layer to contact the second contact plugs thereby connecting the word line to the first conductivity type region through the second contact plugs contacting the first contact plugs.

19. The method according to claim 17, wherein the first conductivity type region is an N-region, and the second conductivity type regions are P-regions.

20. The method according to claim 17, wherein the semiconductor substrate formed with the first conductivity type region includes a bar type active region.

21. The method according to claim 20, wherein the first conductivity type region is formed on a surface of the active region into a bar type.

22. The method according to claim 17, wherein the second conductivity type regions are formed such that predetermined numbers of the second conductivity type regions spaced apart at first regular intervals are spaced apart at second regular intervals which are greater than the first intervals.
